(19) United States
(12) Patent Application Publication
(10) Pub. No.: US 2002/0042192 A1
(43) Pub. Date: Apr. 11, 2002

(54) Shower head, substrate treatment apparatus and substrate manufacturing method

(75) Inventors: Keiichi Tanaka, Narita-shi (JP); Yasunori Yokoyama, Narita-shi (JP); Takashi Suzuki, Narita-shi (JP); Terukazu Aitani, Narita-shi (JP)

Correspondence Address: MOSER, PATTERSON & SHERIDAN, L.L.P., Suite 1500, 3040 Post Oak Blvd., Houston, TX, 77056, US

(73) Assignee: Applied Materials. Inc.

(21) Appl. No.: 09/973,124

(22) Filed: Oct. 9, 2001

(30) Foreign Application Priority Data
Oct. 11, 2000 (JP) P2000-310854

(51) Int. Cl. H01L 21/20; H01L 21/36; C30B 1/00; H01L 21/31; H01L 21/469

(52) U.S. Cl. 438/485; 438/503; 438/765; 438/785

(57) ABSTRACT

A shower head 10 is disposed inside the process chamber 2 of a plasma CVD apparatus 1. The shower head 10 has a plurality of gas introduction holes 11, and a process gas is supplied via these gas introduction holes 11 to a wafer W which is disposed on a pedestal 5. A rough surface portion B that has been subjected to a bead blasting treatment is formed over the entire surface of the shower head 10 that faces the pedestal 5. As a result, the area of the surface of the shower head 10 that faces the pedestal 5 is increased, so that a uniform high-density plasma is generated inside the process chamber 2.

### BACKGROUND OF THE INVENTION

1. Field of the Invention

The present invention relates to a shower head which supplies a process gas to substrates being treated such as semiconductor wafers or the like that are disposed inside a process chamber, a substrate treatment apparatus which is equipped with this shower head, and a substrate manufacturing method which uses this substrate treatment apparatus to form a film on the surface of the substrates being treated.

2. Description of the Related Art

For example, a CVD apparatus, which is one type of substrate treatment apparatus, comprises a process chamber, a pedestal which is disposed inside this process chamber, and which supports a wafer, a pump which reduces the pressure in the process chamber and evacuates the interior of the process chamber, a gas introduction part which supplies a process gas to the interior of the process chamber, and a plasma generating portion which generates a plasma inside the process chamber. A shower head which has a plurality of gas introduction holes is disposed in the process chamber, and the process gas from the gas introduction part is uniformly supplied to the wafer on the pedestal via this shower head.

In such a plasma CVD apparatus, a wafer is conveyed into the process chamber, in which the pressure has been reduced by means of a pump, and this wafer is placed on the pedestal. Then, the process gas is introduced onto the surface of the wafer via the shower head, and a plasma is produced inside the process chamber by the plasma generating portion, so that a thin film is formed on the surface of the wafer.

### SUMMARY OF THE INVENTION

However, in a conventional shower head, the surface of the shower head is a mechanically cut end; as a result, the plasma in the process spreads non-uniformly inside the process chamber, so that the plasma density is insufficient. Consequently, there is a possibility that this will cause a drop in the rate of film formation on the wafer, and a deterioration of the uniformity of the film thickness within the wafer surface.

An object of the present invention is to provide a shower head, a substrate treatment apparatus and a substrate manufacturing method that are capable of generating a stable high-density plasma inside a process chamber.

The present invention is a shower head which is disposed in a process chamber, and which has a plurality of gas introduction holes that are used to supply a process gas to a substrate being treated which is disposed inside the process chamber. In this shower head, a rough surface portion is formed over substantially the entire surface of the shower head that faces the substrate being treated when the substrate being treated is disposed inside the process chamber.

For example, in a plasma CVD apparatus which is equipped with a shower head, the area of the surface of the shower head that faces the substrate being treated is increased as a result of a rough surface portion being formed as described above on the surface of the shower head that faces the substrate being treated. Accordingly, a substantially uniform and high-density plasma can be formed inside the process chamber.

Preferably, the rough surface portion is formed by performing a bead blasting treatment on the surface of the shower head that faces the substrate being treated. As a result, the formation of a rough surface portion whose roughness, shape, area and the like are stable can be realized simply and at a low cost.

In this case, the particle size of the blast material used in the bead blasting treatment is preferably #220 to #20. As a result, the surface of the shower head that faces the substrate being treated can be effectively roughened.

Furthermore, the Knoop hardness of the blast material used in the bead blasting treatment is preferably 1000 to 5000 kg/mm². As a result, the surface of the shower head that faces the substrate being treated can be effectively roughened.

For example, the constituent material of the blast material that is used in the bead blasting treatment is either alumina, SiC, SiO₂ or CO₂.

Furthermore, the substrate treatment apparatus of the present invention comprises a process chamber which treats the substrate being treated, a shower head which is disposed in the process chamber and which has a plurality of gas introduction holes that are used to supply a process gas to the surface of the substrate being treated, which is disposed inside the process chamber, and a plasma generating portion which generates a plasma inside the process chamber. A rough surface portion is formed over substantially the entire surface of the shower head that faces the substrate being treated when the substrate being treated is disposed inside the process chamber.

As a result of the provision of a shower head in which a rough surface portion is thus formed on the surface facing the substrate being treated, a stable high-density plasma can be generated inside the process chamber as described above.

Furthermore, the present invention is a substrate manufacturing method in which a film is formed on the surface of the substrate being treated using the above-mentioned substrate treatment apparatus. In this method, the substrate being treated is conveyed into the process chamber, and a film is formed by supplying a process gas to the surface of the substrate being treated, and generating a plasma inside the process chamber.

As a result of the use of a substrate treatment apparatus which is thus equipped with a shower head in which a rough surface portion is formed on the surface that faces the substrate being treated, a stable high-density plasma can be generated inside the process chamber in the film formation treatment as described above.

Preferably, a silicon wafer is used as the substrate being treated, and a titanium silicide film is formed on the surface of this silicon wafer.

In this case, for example, a gas containing TiCl₄ gas is used as the process gas.

Furthermore, a silicon oxide wafer may be used as the substrate being treated, and a titanium film may be formed on the surface of this silicon oxide wafer.

In this case, for example, a gas containing TiCl₄ gas is used as the process gas.

### BRIEF DESCRIPTION OF THE DRAWINGS

FIG. 1 is a schematic structural diagram which shows a plasma CVD apparatus as one embodiment of the substrate treatment apparatus of the present invention;

FIG. 2 is a back view of the shower head shown in FIG. 1;

FIG. 3 is a characteristic graph which shows an example of comparison of the sheet resistance values and uniformity of titanium films formed on the surface of a silicon oxide wafer;

FIG. 4 is a characteristic graph which shows an example of comparison of the sheet resistance values and uniformity of titanium silicide films formed on the surface of a pure silicon wafer;

FIG. 5A is a diagram which shows an example of the distribution of the sheet resistance values of a titanium film formed on the surface of a single silicon oxide wafer in a case where no bead blasting treatment was performed on the surface of the shower head;

FIG. 5B is a diagram which shows an example of the distribution of the sheet resistance values of a titanium film formed on the surface of a single silicon oxide wafer in a case where a bead blasting treatment was performed on the surface of the shower head;

FIG. 6A is a diagram which shows an example of the distribution of the sheet resistance values of a titanium silicide film formed on the surface of a single pure silicon wafer in a case where no bead blasting treatment was performed on the surface of the shower head; and

FIG. 6B is a diagram which shows an example of the distribution of the sheet resistance values of a titanium silicide film formed on the surface of a single pure silicon wafer in a case where a bead blasting treatment was performed on the surface of the shower head.

### DESCRIPTION OF THE PREFERRED EMBODIMENTS

Below, preferred embodiments of the shower head, substrate treatment apparatus and substrate manufacturing method of the present invention will be described with reference to the attached figures.

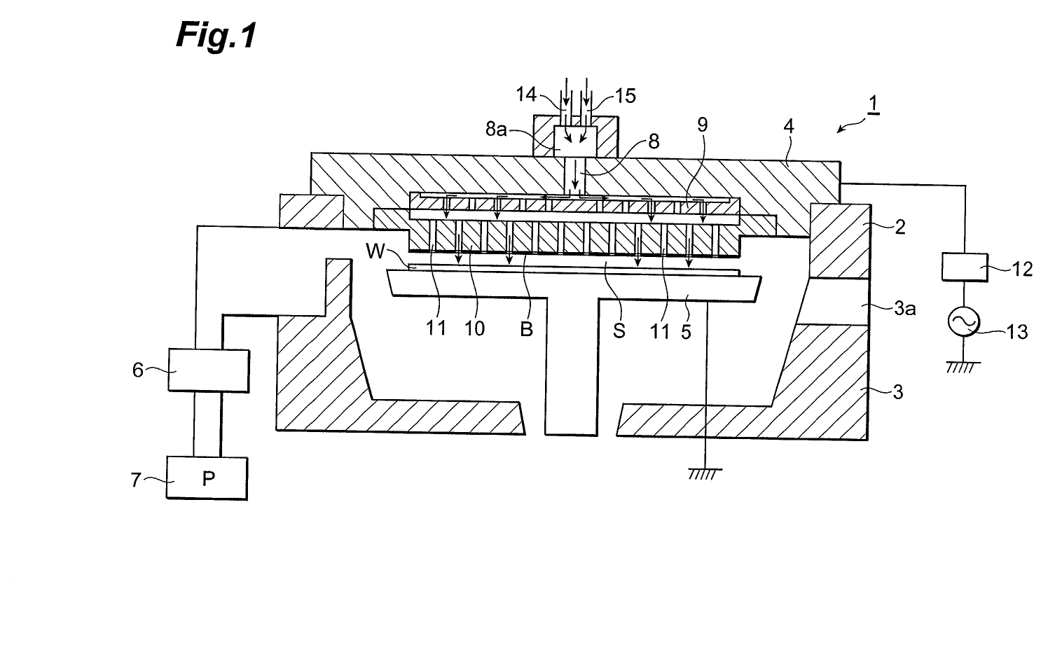

FIG. 1 is a schematic structural diagram which shows a plasma CVD apparatus as one embodiment of the substrate treatment apparatus of the present invention. In the same figure, the plasma CVD apparatus 1 is equipped with a process chamber 2, and this process chamber 2 has a chamber main body 3, and a cover body 4 which disposed on the upper part of this chamber main body 3.

A pedestal 5 which supports a wafer (substrate being treated) W is disposed inside the process chamber 2, and a heater (not shown in the figures) which is used to heat the wafer W is disposed inside this pedestal 5. The pedestal 5 constitutes a lower electrode which consists of a conductive metal such as nickel or the like, and is grounded.

Furthermore, a vacuum pump 7 is connected to the process chamber 2 via a throttle valve 6. This vacuum pump 7 reduces the pressure inside the chamber 2, and evacuates the interior of the chamber 2.

A gas flow passage 8 which includes a gas mixing part 8a is formed in the cover body 4, and pipes 14 and 15 are connected to the gas mixing part 8a. A blocker plate 9 which is fastened by means of bolts is disposed on the undersurface part of the cover body 4, and a plurality of gas introduction holes (not shown in the figures) are formed in this blocker plate 9.

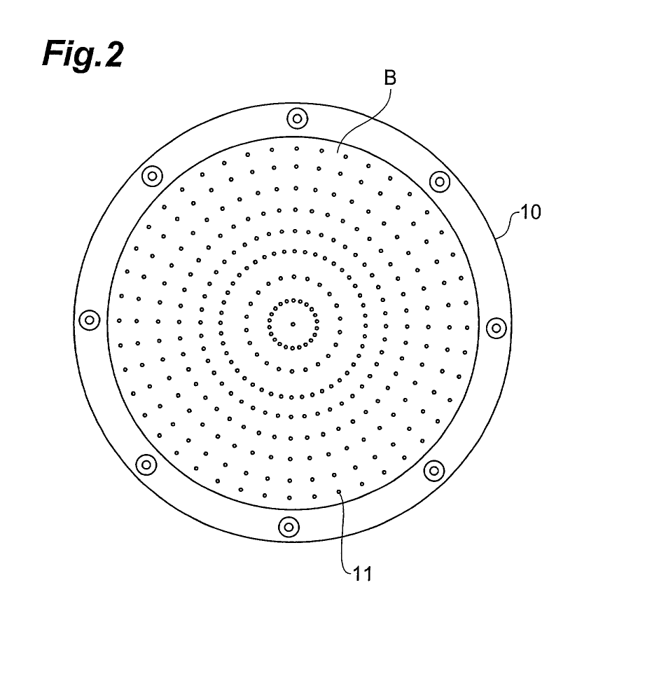

Furthermore, a shower head 10 is disposed beneath the blocker plate 9 so that this shower head 10 faces the pedestal 5. The edge parts of this shower head 10 are fastened to the undersurface part of the cover body 4 by bolts. As is shown in FIG. 2, this shower head 10 is a circular plate that constitutes an upper electrode, and consists of a conductive metal such as nickel or the like. The shower head 10 has a plurality of gas introduction holes 11, and the process gas which is fed from the gas flow passage 8 via the blocker plate 9 passes through these gas introduction holes 11 and is supplied to the wafer W disposed on the pedestal 5. For example, the diameter of these gas introduction holes 11 is a little less than 1 mm.

A rough surface portion B that has been subjected to a bead blasting treatment is formed over the entire surface of the shower head 10 that faces the pedestal 5 (hereafter referred to as the “surface of the shower head 10”) For example, this bead blasting treatment is accomplished by spraying a blast material by means of an air blast machine utilizing compressed air. Alumina, SiC, SiO₂, solid CO₂ (commercial name: dry ice) or the like is used as the blast material. It is desirable that the particle size of the blast material be #220 to #20. Here, # (mesh) is a unit that indicates the coarseness of the particles of a particulate material according to Tyler. Furthermore, it is desirable that the Knoop hardness of the blast material be 1000 to 5000 kg/mm². The surface of the shower head 10 can be effectively roughened by the above treatment. Furthermore, since the rough surface portion B is formed by a bead blasting treatment, a rough surface portion whose roughness, shape, area and the like are more or less constant can be worked simply and at a low cost.

A high-frequency power supply 13 is connected to such a shower head 10 via a matching device 12. When the high-frequency power supply 13 is switched on, a high-frequency power of (e. g.) 350 kHz is applied to the space S between the shower head 10 and the pedestal 5, so that a plasma is generated.

Next, the substrate manufacturing method in which a film formation process is performed on a silicon oxide wafer using the above-mentioned plasma CVD apparatus 1 will be described. First, a silicon wafer W is conveyed by means of a wafer conveying robot (not shown in the figures) through a wafer introduction port 3a into the interior of the process chamber 2, in which the pressure has been reduced to the desired degree of vacuum by the vacuum pump 7, and this wafer W is placed on the pedestal 5, which has been heated to the desired temperature.

Then, a vaporized titanium tetrachloride gas (TiCl₄ gas) using helium as a carrier gas is introduced via the pipe 14, and hydrogen gas (H₂ gas) is introduced via the pipe 15. Furthermore, the TiCl₄ gas and the H₂ gas are introduced in a state in which the flow rates are controlled by an MFC (not shown in the figures) The TiCl₄ gas and H₂ gas are mixed in the mixing part 8a. The resulting mixed gas is supplied to the shower head 10 via the gas flow passage 8 and blocker plate 9, and is uniformly diffused toward the silicon wafer W via the respective gas introduction holes 11 of the shower head 10.

Then, in a state in which the mixed gas introduced into the process chamber 2 is subjected to pressure control by means of the throttle valve 6, the high-frequency power supply 13 is switched on so that high-frequency power is applied to the space S between the shower head 10 and the pedestal 5. As a result, the mixed gas consisting of the TiCl₄ gas and H₂ gas is converted into a plasma in the space S. Accordingly, the TiCl₄ gas and H₂ gas break down, and a bonding reaction between radicalized chlorine and hydrogen is promoted, so that a metallic titanium (Ti) film is formed on the surface of the silicon oxide wafer.

Furthermore, in the film formation process on a pure silicon wafer, a bonding reaction between radicalized chlorine and hydrogen is promoted, and a bonding reaction also occurs at the interface between the silicon and titanium, when a plasma is generated in the space S between the shower head 10 and pedestal 5, so that a titanium silicide (TiSₓ film is formed on the surface of the silicon wafer.

Here, in a case where a bead blasting treatment is not performed on the surface of the shower head 10, so that this surface remains as a mechanical cut end as in conventional devices, the plasma spreads non-uniformly inside the process chamber 2 during the film formation process, so that the plasma density is insufficient. As a result, there is possibility that the film formation rate on the wafer W will drop, and that the film thickness within the surface of the wafer W will be non-uniform. Furthermore, titanium chloride (TiClₓ) type by-products containing titanium which are generated by the film formation process are deposited non-uniformly on the surface of the shower head 10, so that that is also a possibility that the continuous stability of film formation will be lost. Moreover, since the radiant heat reaching the wafer W from the shower head 10 is non-uniform, there is a possibility of a further drop in the uniformity of the film thickness, especially in cases where a titanium silicide film is formed on the surface of a pure silicon wafer W. In addition, individual differences between shower heads 10 are also large.

On the other hand, in a case where a bead blasting treatment is performed on the surface of the shower head 10, the area of the surface of the shower head 10 is increased, so that a high-density plasma is generated inside the process chamber 2. Furthermore, since the roughness of the surface of the shower head 10 is made uniform by the bead blasting treatment, the plasma generated inside the process chamber 2 is uniform. Accordingly, the reaction efficiency is good, and the film formation rate on the wafer W and the uniformity of the film thickness within the wafer surface are improved. Furthermore, Ti and TiClₓ type by-products or the like generated by the film formation process are uniformly deposited on the surface of the shower head 10 by the plasma, which is generated uniformly an with a high density. Accordingly, the continuous stability of film formation is improved. In addition, since the radiant heat reaching the wafer W from the shower head 10 is made uniform, the uniformity of the film thickness is greatly improved especially in the case of a titanium silicide film formed on a pure silicon wafer. Furthermore, individual differences between shower heads 10 are extremely slight.

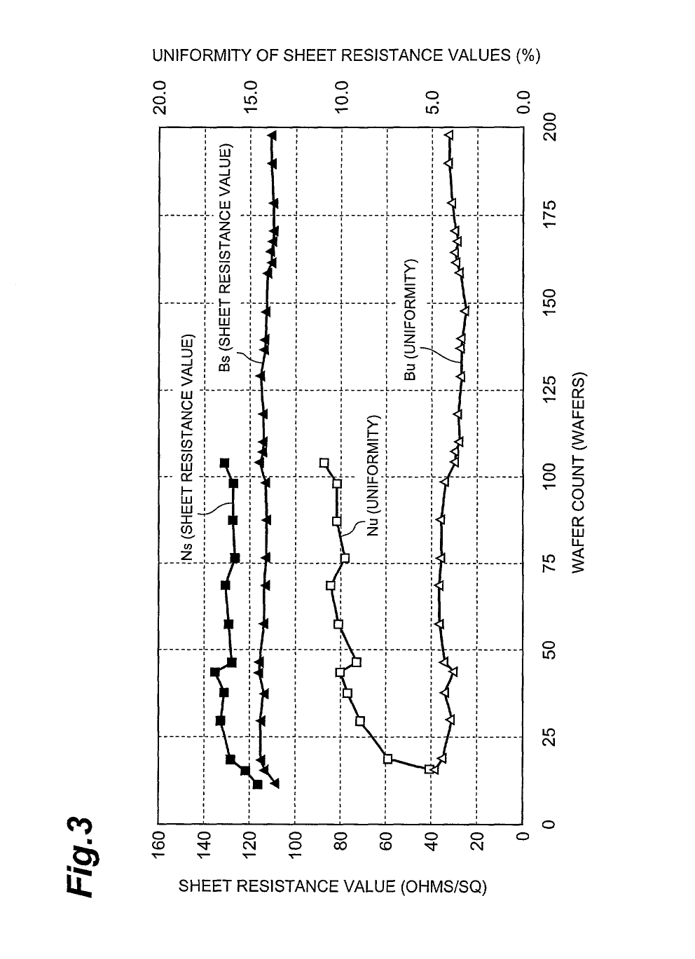

Examples of the results obtained in cases where a bead blasting treatment is thus performed on the surface of the shower head 10 are compared with the results obtained when such a treatment is not performed in FIG. 3 through FIG. 6.

FIG. 3 shows the sheet resistance values and uniformity of these values for a titanium film formed on a silicon oxide wafer. In the same figure, the black squares Ns indicate sheet resistance values of the titanium film in a case where no bead blasting treatment was performed on the shower head, and the black triangles Bs indicate the sheet resistance values of the titanium film in a case where a bead blasting treatment was performed on the shower head. The white squares Nu indicate the uniformity of the sheet resistance values of the titanium film in a case where no bead blasting treatment was performed on the shower head, and the white triangles Bu indicate the uniformity of the sheet resistance values of the titanium film in a case where a bead blasting treatment was performed on the shower head. Furthermore, the horizontal axis indicates the count of the wafers W, the vertical axis on the left side indicates the sheet resistance values of the titanium film, and the vertical axis on the right side indicates the uniformity of the sheet resistance values of the titanium film. Furthermore, the number of measurement points within the surface of a single wafer was 49 points, and the uniformity of the sheet resistance values was calculated using the following formula:

(standard deviation for 49 points within the surface of a single wafer)/(mean value for 49 points within the surface of a single wafer)×100%

As is seen from this FIG. 3, variation in the uniformity (mean value) of the sheet resistance values for each wafer W is reduced by performing a bead blasting treatment on the surface of the shower head 10.

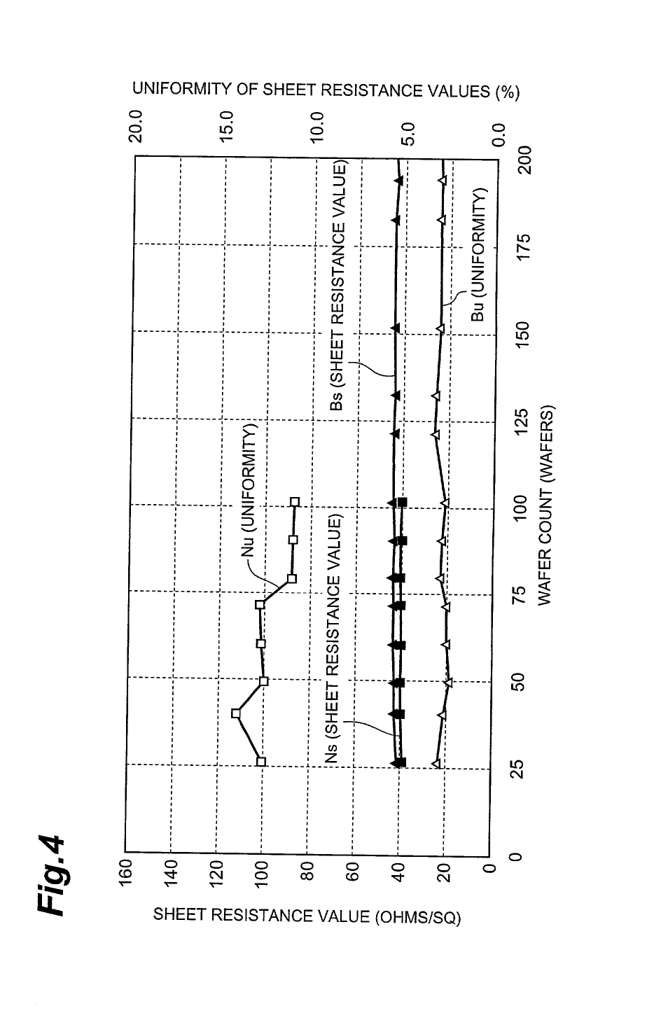

FIG. 4 shows the sheet resistance values and uniformity of these values for a titanium silicide film formed on the surface of a pure silicon wafer. Furthermore, this characteristic graph may be viewed in the same manner as FIG. 3. As is seen from this figure, the variation in the uniformity (mean value) of the sheet resistance values for each wafer W is reduced by performing a bead blasting treatment on the surface of the shower head 10.

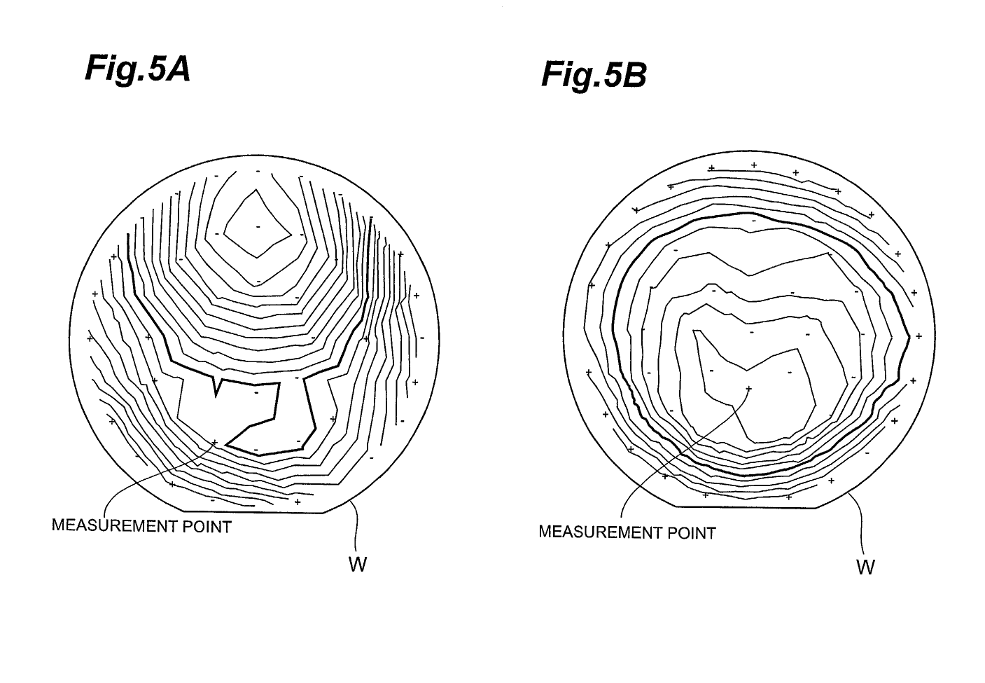

FIG. 5 shows the distribution of the sheet resistance values in a titanium film formed on the surface of a single silicon oxide wafer W. FIG. 5A shows the distribution in a case where no bead blasting treatment was performed on the shower head, and FIG. 5B shows the distribution in a case where a bead blasting treatment was performed on the shower head. Furthermore, in the case as well, the number of measurement points was 49 points.

In FIG. 5A, the maximum value of the sheet resistance is 155.1 ohms/sq, the minimum value of the sheet resistance is 124.85 ohms/sq, and the deviation is 30.25 ohms/sq. On the other hand, in FIG. 5B, the maximum value of the sheet resistance is 122.74 ohms/sq, the minimum value of the sheet resistance is 109.24 ohms/sq, and the deviation is 13.5 ohms/sq. It is seen from these results that the uniformity of the sheet resistance values within the surface of a single wafer is improved by performing a bead blasting treatment on the surface of the shower head 10. Furthermore, as is seen from FIG. 5, the distribution of the sheet resistance values is good in cases where a bead blasting treatment is performed on the surface of the shower head 10. In addition, the sheet resistance values are lowered, so that the film formation rate is improved.

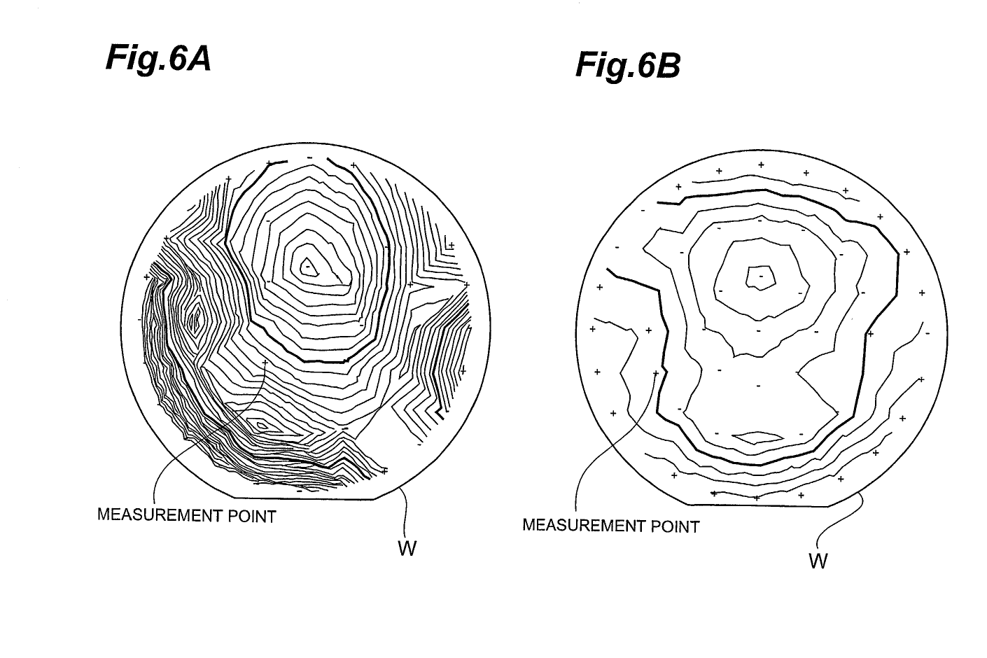

FIG. 6 shows the distribution of the sheet resistance values in a titanium silicide film formed on the surface of a single pure silicon wafer W. FIG. 6A shows the distribution in a case where no bead blasting treatment was performed on the shower head, and FIG. 6B shows the distribution in a case where a bead blasting treatment was performed on the shower head,

In FIG. 6A, the maximum value of the sheet resistance is 49.375 ohms/sq, the minimum value of the sheet resistance is 28.432 ohms/sq, and the deviation is 20.943 ohms/sq. On the other hand, in FIG. 6B, the maximum value of the sheet resistance is 47.99 ohms/sq, the minimum value of the sheet resistance is 44.061 ohms/sq, and the deviation is 3.929 ohms/sq. As is seen from these results, the uniformity of the sheet resistance values within the surface of a single wafer is improved by performing a bead blasting treatment on the surface of the shower head 10.

Furthermore, the present invention is not limited to the embodiments described above. For example, in the embodiments described above, a titanium film and a titanium silicide film were formed on wafers W. However, the present invention is not particularly limited to such film formation, and could also be used for the formation of other films such as aluminum films, tungsten films or the like.

Furthermore, in the above-mentioned embodiments, a plasma CVD apparatus was used; however, the present invention could also be applied to other substrate treatment apparatuses equipped with a shower head.

Furthermore, in the above-mentioned embodiments, a rough surface portion B was formed by performing a bead blasting treatment on the surface of the shower head 10. However, the present invention is not particularly limited to a bead blasting treatment; for example, a rough surface portion which preferably has a roughness that is finer than the diameter of the gas introduction holes 11 could also be formed by filing the surface of the shower head 10 with a paper file or the like.

What is claimed Is:

1. A shower head which is disposed in a process chamber, and which has a plurality of gas introduction holes that are used to supply a process gas to a substrate being treated which is disposed inside said process chamber, wherein a rough surface portion is formed over substantially the entire surface of the shower head that faces the said substrate being treated when said substrate being treated is disposed inside said process chamber.

2. The shower head according to claim 1, wherein said rough surface portion is formed by performing a bead blasting treatment on the surface that faces said substrate being treated.

3. The shower head according to claim 2, wherein the particle size of the blast material used in said bead blasting treatment is #220 to #20.

4. The shower head according to claim 2, wherein the Knoop hardness of the blast material used in the bead blasting treatment is 1000 to 5000 kg/mm².

5. The shower head according to claim 2, wherein the constituent material of the blast material used in said bead blasting treatment is alumina, SiC, SiO₂ or CO₂.

6. A substrate treatment apparatus comprising:
a process chamber which treats the substrate being treated;
a shower head which is disposed in said process chamber, and which has a plurality of gas introduction holes that are used to supply a process gas to said substrate being treated which is disposed inside said process chamber; and
a plasma generating portion which generates a plasma inside said process chamber, wherein a rough surface portion is formed over substantially the entire surface of said shower head that faces said substrate being treated when said substrate being treated is disposed inside said process chamber.

7. A substrate manufacturing method in which a film is formed on the surface of the substrate being treated using the substrate treatment apparatus according to claim 6, wherein said substrate being treated is conveyed into said process chamber, and a film is formed by supplying said process gas to said substrate being treated, and generating a plasma inside said process chamber.

8. The substrate manufacturing method according to claim 7, wherein a silicon wafer is used as said substrate being treated, and a titanium silicide film is formed on the surface of said silicon wafer.

9. The substrate manufacturing method according to claim 8, wherein a gas containing TiOl₄ gas is used as said process gas.

10. The substrate manufacturing method according to claim 7, wherein a silicon oxide wafer is used as said substrate being treated, and a titanium film is formed on the surface of said silicon oxide wafer.

11. The substrate manufacturing method according to claim 10, wherein a gas containing TiOl₄ gas is used as said process gas.
